(19) United States
(12) Patent Application Publication
(10) Pub. No.: US 2003/0099139 A1
(43) Pub. Date: May 29, 2003

(54) Memory test apparatus and method of testing

(76) Inventors: Igor Anatolievich Abrosimov, St.Petersburg (RU); Maxim Evgenievich Azarov, Vsevolozhsk (RU); Oleg Nikolayevich Khavin, St.Petersburg (RU); Amir Magomed Kourbanov, St.Petersburg (RU); Alexey Mikhailovich Pankratov, St.Petersburg (RU); Sergey Mikhailovich Pyko, St.Petersburg (RU)

Correspondence Address: Igor Abrosimov, Office 501, 58, Moika Embankment, St.Petersburg, RU

(21) Appl. No.: 10/225,528

(22) Filed: Aug. 22, 2002

(30) Foreign Application Priority Data
Aug. 24, 2001 (US) US 60/314,496

(51) Int. Cl. G11C 7/00

(52) U.S. Cl. 365/200

(57) ABSTRACT

A memory tester for testing memory devices. The tester comprises a test header, an algorithmic pattern generator (APG) and a fault logic device. In the memory tester according to the invention successive data processing algorithms with minimum feedbacks are used. The APG generates test instructions wherein each instruction has fields controlling respective functional parts of the tester. The control signals are stored together with data signals in an instruction memory that provides high speed test pattern generation. For different memory types, the width of instruction memory varies.

### CROSS-REFERENCES TO RELATED APPLICATIONS

This application is a Continuation-in-Part of U.S. Provisional application No. 60/314,496 filed on Aug. 24, 2001.

### BACKGROUND OF THE INVENTION

1. Field of the Invention

The present invention relates to automatic testing equipment (ATE) for testing memory devices. Usually, a test system includes a tester and an external PC connected thereto for controlling the tester and processing and displaying test results. However, these functions can be performed by a controller incorporated in the tester.

Hourly increasing operating speeds of all computer components including memory devices result in growing demands on operating speeds of automatic testing equipment. More often than not, quite recently developed testers turn to be behind the times.

2. Description of the Related Art

U.S. Pat. No. 5,995,424 discloses a memory test system comprising a 32-bit RISC CPU in communication with address/data/control bus, and with processor clock which generates a 40 MHz signal providing timing for CPU. Also in communication with the bus is a ROM and a RAM providing a non-volatile storage and temporary storage, respectively, for test software and data; a communications interface providing connection to an external printer or PC; I/O interface leading to a display and input keys; and memory test controller comprising a state machine and control enable logic. CPU executes software program codes stored in ROM and uses RAM for temporary, intermediate, and variables storage. In this tester, the address/data/control bus which is actually a unibus is used for communication between units, while generating test signals and reading faults is controlled by one unit (CPU). This results in various feedbacks in the logical operational structure of the tester, which feedbacks lead to insufficient operation speed of this system. Further, the system is designed for testing synchronous memory only.

While testing memory devices, it is desirable to check their physical parameters. However, this system does not have means for performing this kind of testing.

A high speed test pattern generator is known from U.S. Pat. No. 5,883,905 comprising a sequencer and address and data generators in communication with instruction memory. However, the known pattern generator is not scalable, i.e., it does not provide the extension of instruction fields on tester units other than data and address generators, such as test header.

### BRIEF SUMMARY OF THE INVENTION

The object of the invention is providing a high speed memory tester capable of testing various kinds of memory devices and measuring physical characteristics thereof.

Another object of the invention is providing a high speed memory tester which is easily scalable.

Thus, in one aspect of the invention, a test apparatus is provided for testing a memory device under test, the test apparatus comprising a scalable algorithmic test pattern generator for generating test instructions; a detachable header for connecting to a memory device under test (DUT); and a fault logger for analyzing results of the test, connected to the DUT; the test pattern generator, the header, DUT and fault logger being connected in series, wherein the test pattern generator includes a sequencer, an address generator and a data generator, the sequencer being operating independently from the operation of the data and address generators, thereby providing for the high speed conveyor transmission and treatment of data within the test apparatus.

In another aspect, a memory test system is provided comprising a test apparatus for testing a memory device and a computer connected thereto, the test apparatus comprising a scalable test pattern generator for generating test instructions, a fault logger and a detachable header comprising a header board connected to the test pattern generator and the fault logger, and a memory device interface board connected to the header board by means of pin electronics cards, wherein the algorithmic pattern generator includes a sequencer, address generator and data generator, each in communication with an instruction RAM, wherein test data is transmitted continuously through a one-way data transmission means from the algorithmic pattern generator to the memory device under test, and from the memory device under test to the fault logic device.

According to the present invention, the test pattern generator, the header, DUT and the fault logger are connected in series in the absence of either local or global feedback loops thereby providing for the conveyor treatment of data within the test apparatus and test system in whole. Both generation and transmission of test vectors, and the subsequent treatment of results of the test are performed in a similar conveyor-like manner that provides for high speed of testing.

According to the invention, preferably, the test pattern generator comprises more than one data generator, while address generator is segmented into three units, row, column generator and bank generator, thereby a test vector can be generated in one machine cycle. Alternatively, the address generator and data generator can be operated as a random generator.

Each said instruction word retrieved from the instruction memory includes separate fields controlling the operation of the sequencer, address generator and data generator, respectively, so that more than one operation can be performed within one machine cycle.

The test pattern generator according to a preferred embodiment of the present invention comprises a pattern generator, a data memory, and random generator. The pattern generator is operable in three modes.

According to a first mode, a pre-calculated test vector is retrieved from the data memory, wherein the test vector can be represented by any possible sequence of “1”s and “0”s. According to a second mode, a test vector is generated using FPGA in accordance with the current DUT address; and according to the third mode, the test data is generated by a random generator.

The test apparatus according to the invention provides for the width extension of instruction words retrieved from the Instruction Memory. The width is extended by increasing the number of memory chips addressable by Test Instruction Sequencer. Each instruction word comprises at least partially or completely decoded instruction that increases the generation of test vectors.

As a result, (a) several commands, or operations can be implemented within one machine cycle; (b) several commands, or operations, can be performed simultaneously (where the command word comprises several fields controlling operations of several functional units of the tester); and (c) a instruction word can include data fields in addition to address fields.

According to a preferred embodiment of the invention, the fault logger comprises a plurality of systolic elements that enabling the segmenting of the fault logger into a plurality of fault logger units.

The fault logger can be operated in two modes, namely, a direct mode, when the fault logger is used for the treatment of fault data, and the reverse mode, when the fault logger is used for generation of test vectors.

Also, preferably, the buffer memory used in the test apparatus of the present invention has an extended structure and is segmented into a plurality of memory units, wherein each unit interacts with a respective source of information while the whole plurality of memory units is controlled by a common control unit. As a result, the memory capacity is increased so that the duration of the uninterrupted operation is increased also.

Still one more important feature of the invention is that several test units can be operated in parallel in a Master-Slave manner that enables extending the width of test vectors.

Different transmission channels including USB, Ethernet, LVDS channels and the like, can be used to incorporate the tester of the invention into any computer environment. The use of LVDS channel with AGP interface card instead of typically used PC video card provides the highest possible transfer rate for transfer of information for the conventional testers.

### BRIEF DESCRIPTION OF THE SEVERAL VIEWS OF THE DRAWINGS

Reference is now made to the following description taken in conjunction with the following drawings in which:

FIG. 1 shows the block diagram of the tester according to the invention;

FIG. 2 shows three schematic sectional views, that is elevation view, side view and plan view of the tester with internal PC;

FIG. 3 shows three schematic sectional views, that is elevation view, side view and plan view of the tester without internal PC;

FIGS. 4 and 5 show a test system including a number of interconnected testers with and without an internal PC, respectively.

FIG. 6 shows a test system including a number of testers connected via internal PCs.

FIG. 7 shows a test system including a number of interconnected testers, some of the testers having internal PC;

FIG. 8 schematically shows a USB network within the tester;

FIG. 9 shows a block diagram of the APG;

FIG. 10 schematically shows topology of the APG;

FIG. 11 schematically illustrates basic data flow in the APG;

FIG. 13 shows a block diagram of the address generator;

FIG. 14 shows a block diagram of the data generator;

FIG. 15 shows a functional diagram of the data generator;

FIG. 16 shows a block diagram of the FPG;

FIG. 17 shows a block diagram of the fault logger;

FIG. 18 shows a block diagram of the fault logger master;

FIG. 19 shows a block diagram of the systolic element for the fault logger;

FIG. 20 shows a diagram of the circuit defining the name (number) of the systolic element;

FIG. 21 shows a block diagram of the serial bus controller;

FIG. 22 shows a timing diagram for the serial bus controller;

FIG. 23 schematically illustrates logic operations with the data;

FIG. 24 schematically illustrates fault calculations;

FIG. 25 shows a diagram of the flow fault channel; and

FIG. 26 shows a diagram of the LVDS receiver connected to an LVDS transmitter on a single Virtex-E FPGA

### DETAILED DESCRIPTION OF THE INVENTION

The following abbreviations are used in the following description of the present application:

APG—Algorithmic Pattern Generator;

USB—Universal Serial Bus;

DUT—Device Under Test.

PEC—Pin Electronics Cards

AGP—Accelerated Graphics Port

SSTL2—Stub Series Terminated Logic for 2.5V

LVCMOS2 (CMOS2)—Low-Voltage CMOS for 2.5 Volts

LVPECL—Low Voltage Positive Emitter Coupled Logic

LVDS—Low Voltage Differential Signal

GTL—Gunning Transceiver Logic

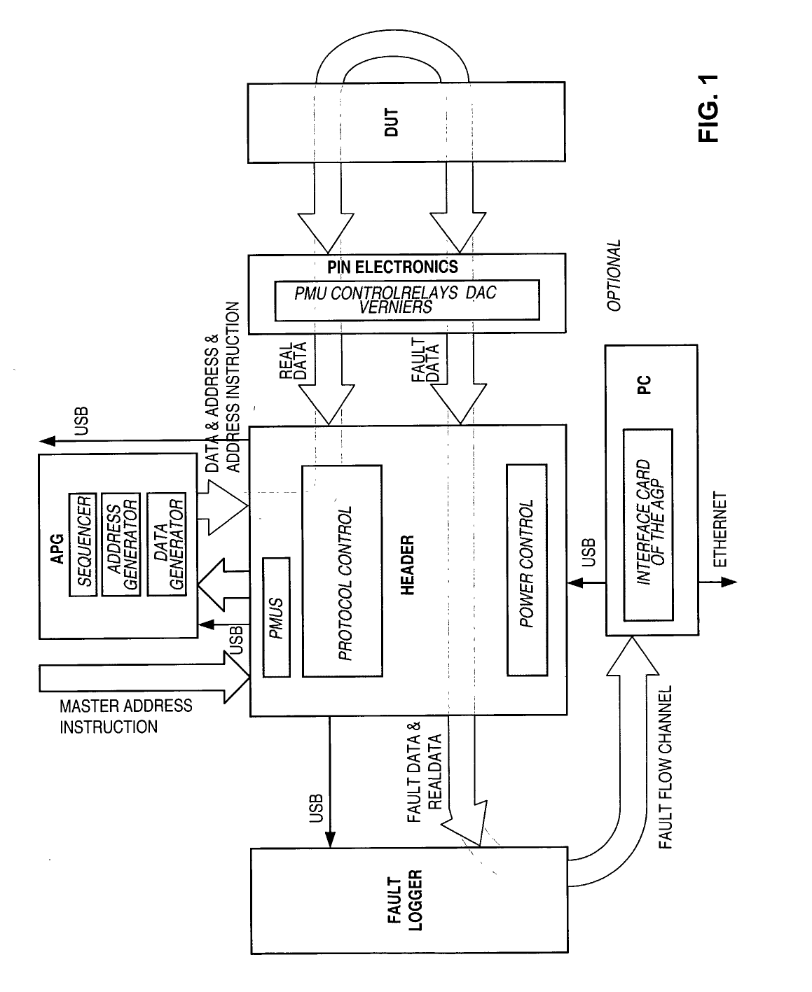

As seen in FIG. 1, the memory tester generally comprises an algorithmic pattern generator (APG) for generating test patterns for testing a memory device under test (DUT) and a fault logic device (FL or fault logger) for capturing and processing the result fault data. Structurally, each of the two main parts is incorporated in a base unit and formed as a card. A tester can include any number of APG or FL cards. This provides for the increase in test operation speed by multiplexing.

The base unit is connected to a detachable header described below in more detail.

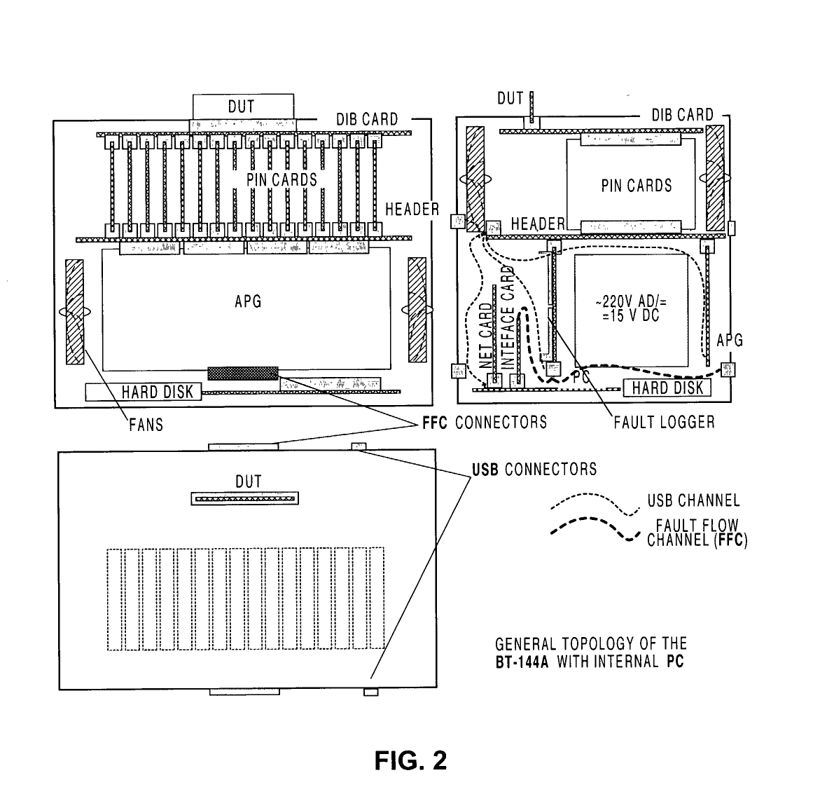

In FIG. 2, an example embodiment of the tester according to the invention is shown. For the simplicity reasons, means for detaching the header from the base unit are not shown.

The base unit further comprises a main power supply unit.

Optionally, the base unit comprises an internal PC for performing some of the functions of the external PC, which functions are otherwise performed by the external PC connected via the USB bus. These functions include, e.g., system configuration, loading test programs, preconditioning fault cards, compression, and controlling the automated testing system for memory modules. The internal PC has an advantage for bitmap and vector processing as it is connected via the AGP bus.

The detachable header comprises a header board and a device interface board (DIB) connected with pin electronics cards (PEC). Pin electronics cards contain relays, delay verniers, DACs, as well as the drive and receiver electronics. They handle the multiplexing of data, calibration and signal switching for parametric measurements. Aside from interfacing signals from the header board to the DIB, the Pin Electronics also provide DACs and relays for signal routing.

The header board acts as a backplane that routes signals between the APG, Fault Logger and PECs. The configuration of the header depends on DUT type. Different headers may be designed specifically for SDRAM, DDR I, DDR II, FLASH and SRAM, as well as for Direct RAMBUS. The header includes a 4 channel USB HUB and USB controller.

The APG provides a micro-instruction address which can be used by the header to expand the instruction space to cover different multiplex or special technology requirements, with a depth of 128K/256K, running at full APG speed.

The APG includes a proprietary bus for high speed data exchange between APG and Fault Loggers, in addition to the local bus which controls the test system.

USB has access to all drivers, relays and PMU signals via the local bus for diagnostic and monitoring purposes.

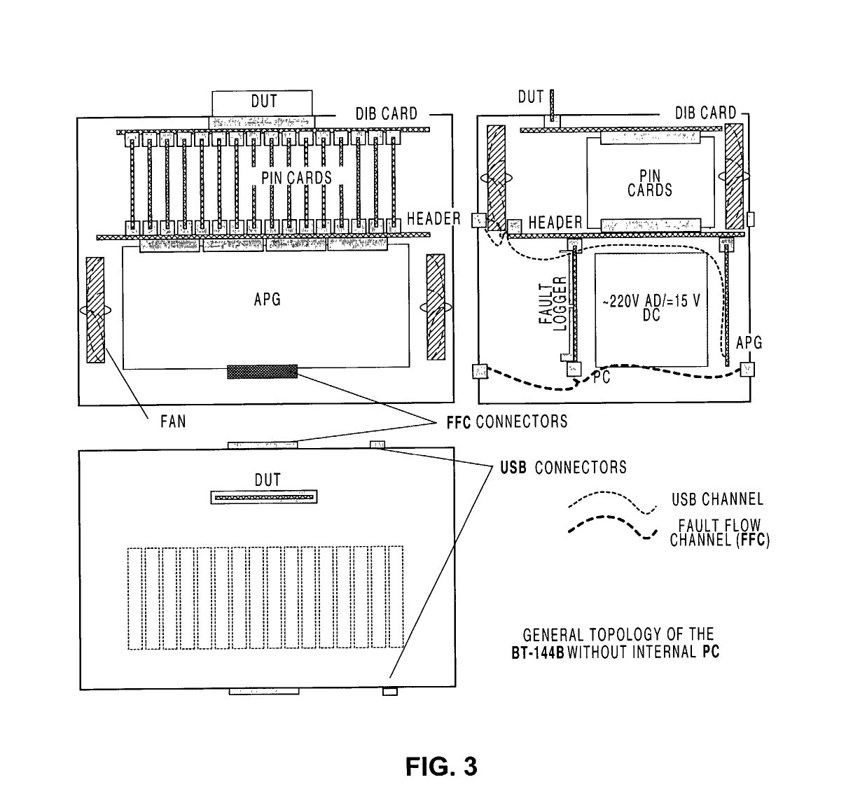

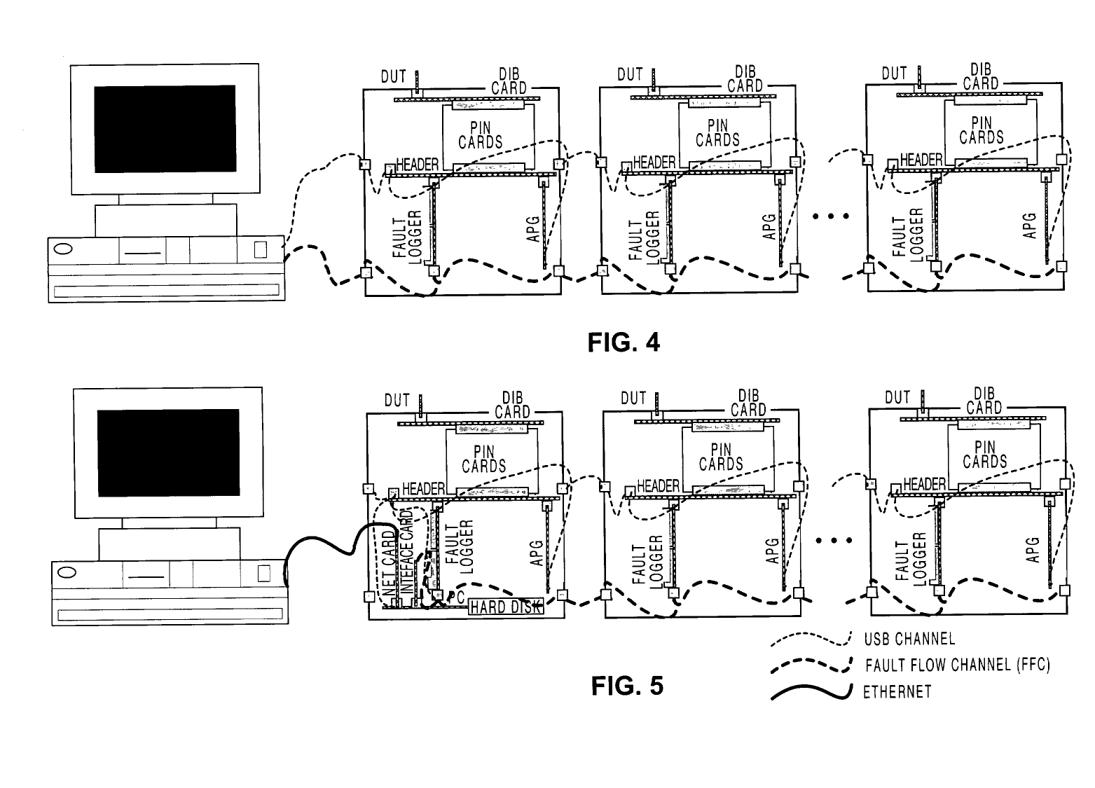

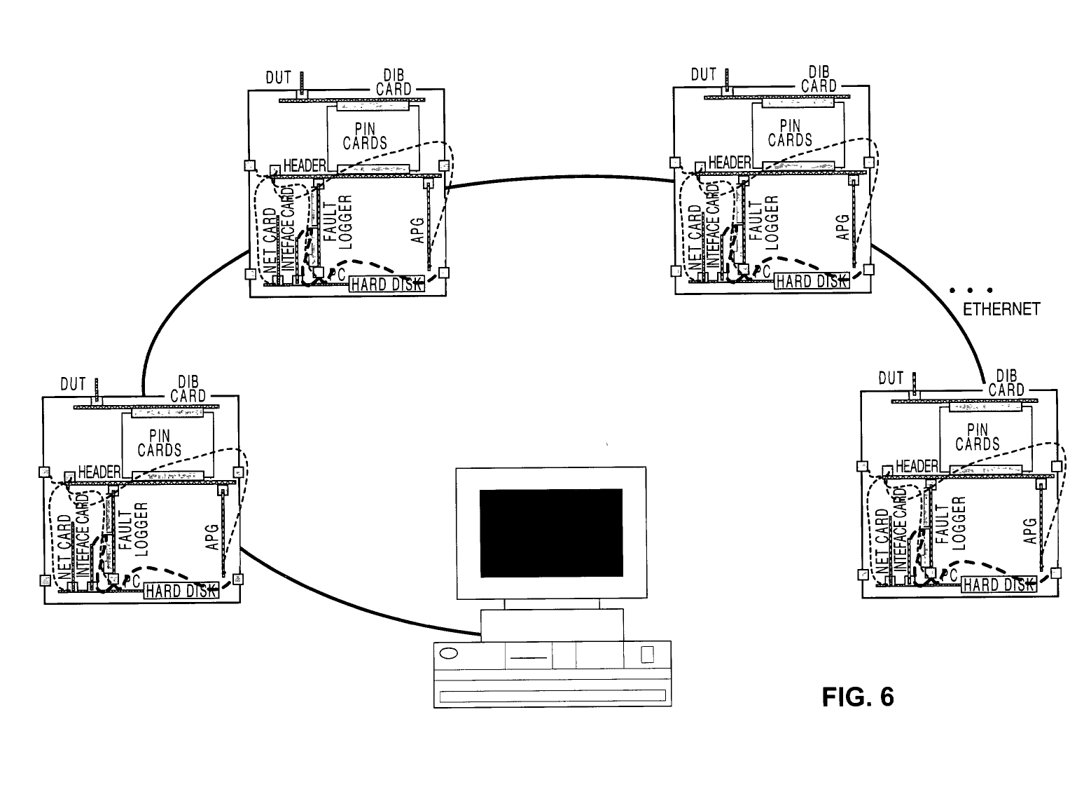

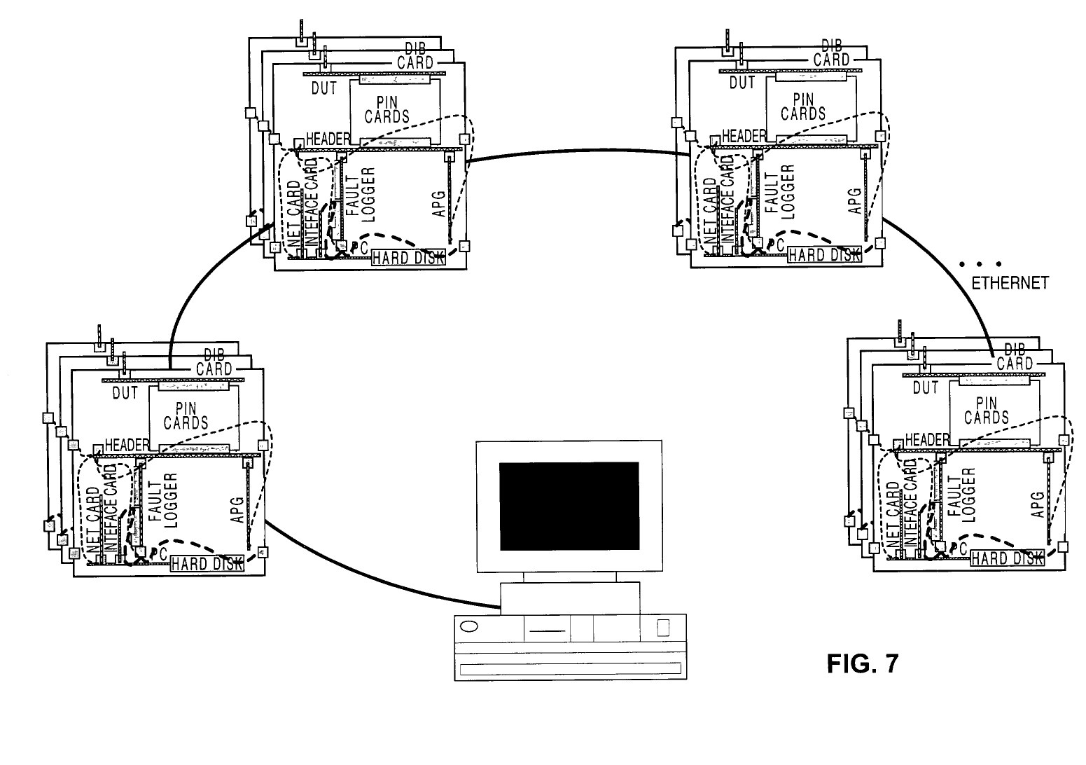

It shall be appreciated that various modifications of the test system are possible within the scope of the present invention, that is, a tester having an internal PC, as shown in FIG. 2, and a tester having no internal PC, as shown in FIG. 3. Other possible modifications of the test system are shown in FIGS. 4-6, the system comprising testers having no internal PCs (FIG. 4), connected via a USB, a compound system with different testers (FIG. 5), a system with testers having internal PCs incorporated via Ethernet (FIG. 6) and a compound system with net communication (FIG. 7).

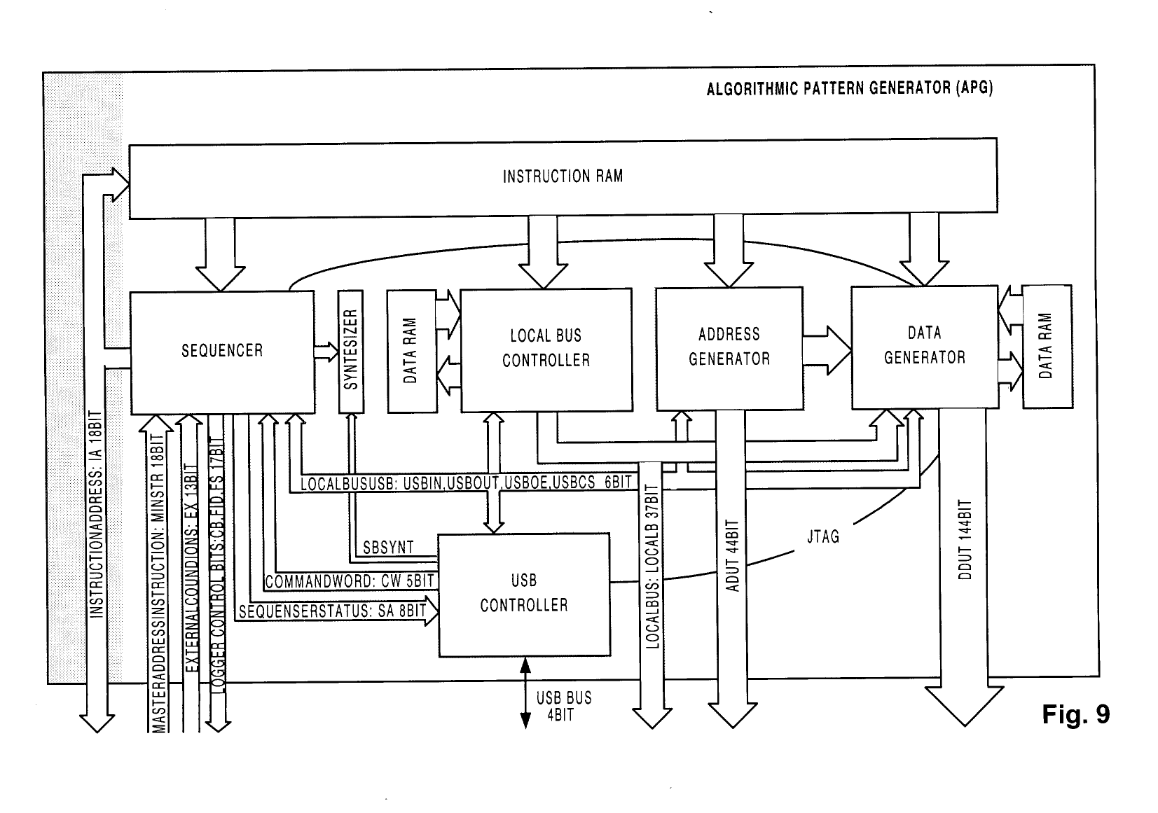

FIG. 9 shows a block diagram of the APG.

APG includes a sequencer, address generator, data generator, and interface control block. APG further includes an instruction memory providing instructions for the above parts. The Instruction Memory is on the APG Board, except for the portion generating the DUT-dependent control signals—this section resides on the header. An instruction has fields, each field controlling a functional part of the tester: the sequencer, address generator, data generator, interface control, PMU, fault logger and protocol control. A part of this memory, which controls the DUT dependent items, is located on a header. Different header types can have different instruction memory widths according to the header complexity.

The sequencer provides a flow of addresses for instructions at full tester speed. The address generator provides full DUT addresses (with mapping capability). The data generator provides data for the DUT, with functional pattern generation and polarity control capabilities. The interface control block provides data and addresses on the local bus to load registers, LUT etc. Allowing only one sequencer in multi-APG configurations to address the instruction memory provides APG cascadability.

The APG is powered from a single 15 V (120W) source. In the device, the following set of voltages is formed: +1.8V, +2.5V, +3.3V. The voltage 1.8V is used to supply the kernels FPGAs. The 3.3V source is used to supply the kernels of memory chips, synthesizer frequency and chips of an LVPECL series. The +2.5V source is necessary to supply the output FPGAs and memory.

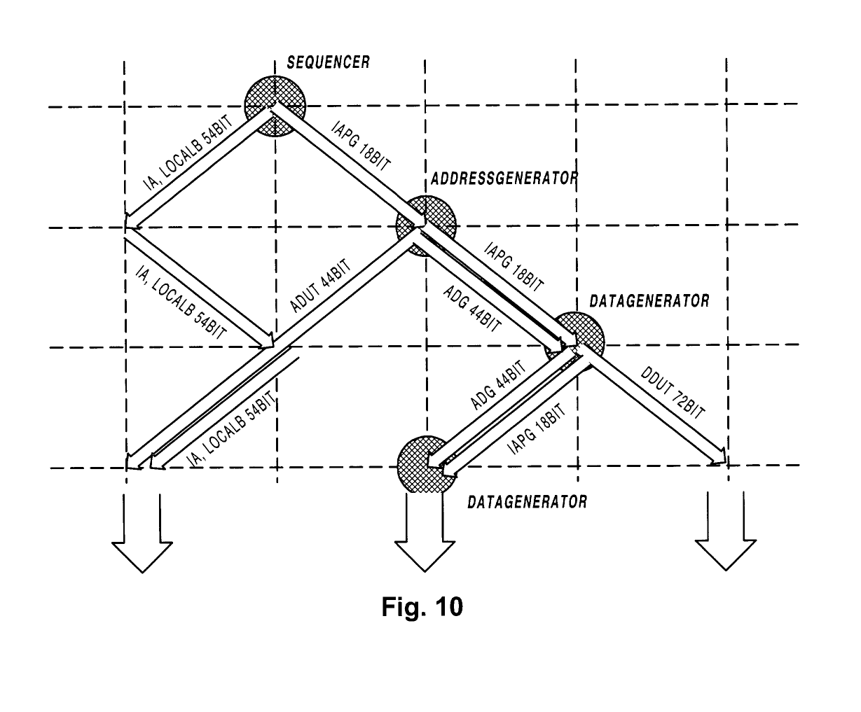

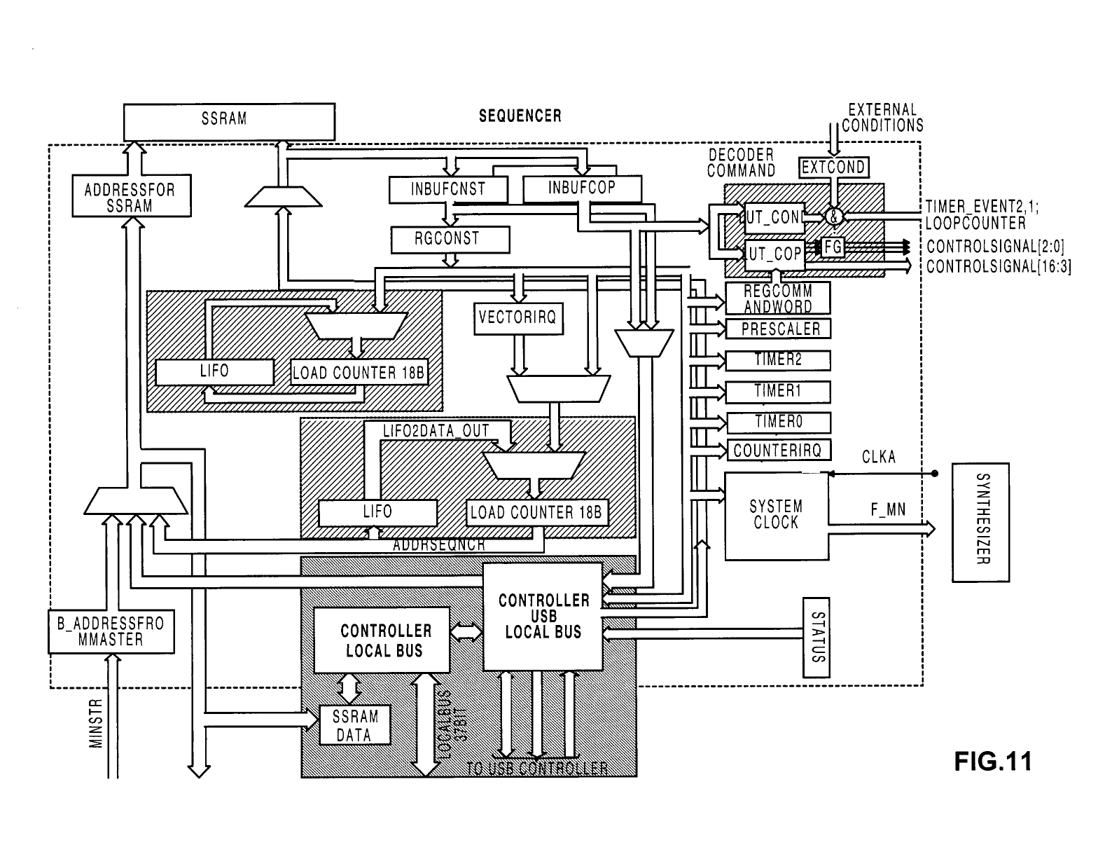

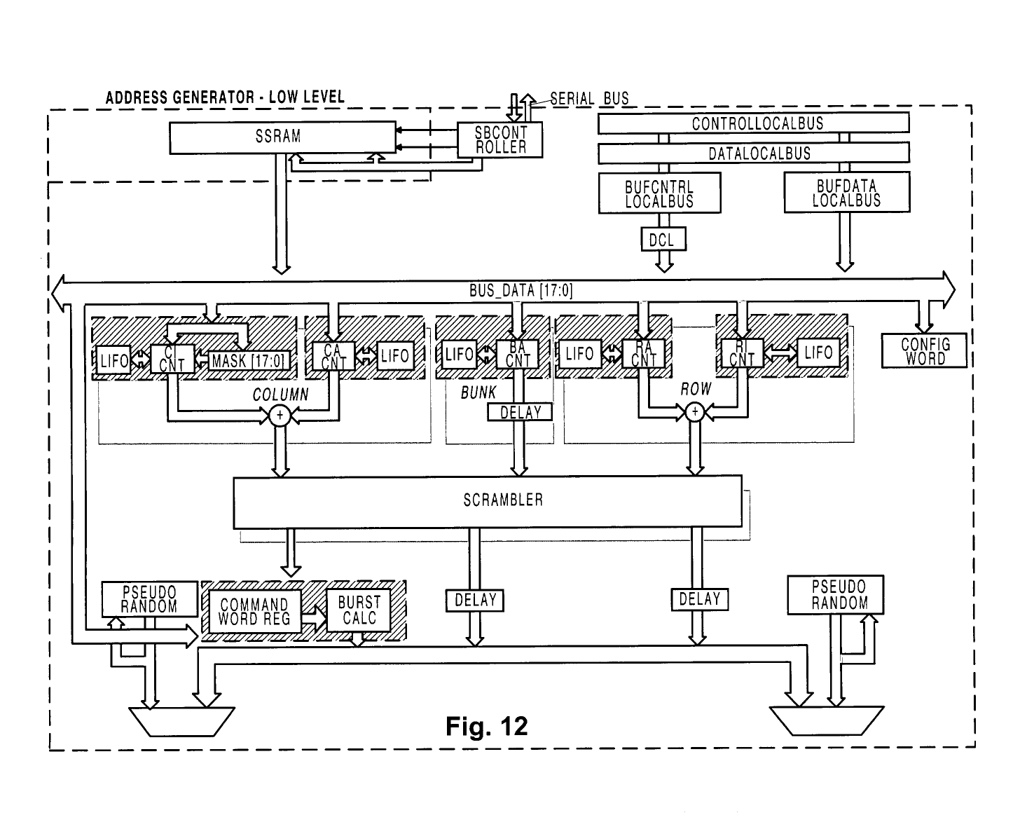

The topology of the APG board is given in FIG. 10, while FIG. 11 shows the basic information flows on the board.

The APG generates 144 bits of data on each clock cycle at 266 MHz at full width. Test data are supplied either from the APG or from a vector table containing up to 128K independent vectors (or 256K depending on the chips fitted). Vectors after this limit must be supplied from the fault logger. Full data polarity encoding is provided (scrambling all DQ bits by a vector determined by the 44 bit wide address field).

The transformation of DQ bits may be performed based on both the logical and physical address with account to the packet operation of the tester. This is provided by using a special descrambler providing both direct and reverse transformation of addresses, e.g. such as described in U.S. Pat. No. 6,393,543 by the same applicants.

The scrambler can implement XOR, NOT and AND. Also, full physical to logical address transformation is provided (scrambling all address bits by a vector determined by the 44 bit wide address field).

Interface to the pin cards uses standard SSTL2 levels and is synchronous; that is, the data is accompanied by a clock signal.

The test program is held in the instruction memory, of a maximal length of 128K using 128K×36 bit SRAM; this can be increased to 256K using 256K×36 chips in the same footprint.

The pipeline depth of the branch processor is 15, but may be, for example, from 5 to 20 as well. This means the branch is executed without any apparent latency if the branches are separated by at least 15 cycles. The APG uses speculative branch prediction and command fetches.

13 input lines are used for external events.

Eight bits and a clock are generated for the Fault Logger control: 1 bit is normally a fault strobe, 7 bits are command bits.

Eight bit field is reserved for use, e.g., as a Fault_ID where various types of fault are stored. A memory is provided for storing predefined pairs of address and data, in table form, for transfer through the internal bus to control relays, verniers, the matrix for address and data scrambling, configuration data and so on. The depth of the given memory is 128K (256K).

The APG supports a “master/slave” mode that allows the width of a test signal vector to be expanded.

APG frequency can be 0.001 Hz (actually, 133*10ˆ 6/2ˆ 36) to 266 MHz. This is achieved by generating a signal between 133 MHz and 266 MHz, using a VCO which is the base clock, and dividing this using a 36 bit prescaler. The base clock frequency is defined by the expression: Fclock=1.0416×M/N, where M and N are 9 and 2 bit numbers respectively.

The clock has a peak-to-peak jitter less than ±50 ps, mostly due to VCO noise and clock distribution circuitry.

In addition to all the capabilities of the existing bT72 APG, three timers with a depth of 36 bits are also accessible by the test program.

The APG contains a built-in USB interface: the first iteration will be USB 1.1 increasing to USB 2 as the chipsets become available. The USB channel is used for configuring, loading the programs and controlling the APG.

The APG is powered from a single 15V supply (120W), with local supplies generated on board.

The APG boot sequence is:

1. Initialise the USB controller, involving sending it its initialisation program. This program load is conducted under the control of either an external or internal PC.

2. Enter the configuration program for the FPGA, via the USB port. The 8051 micro-controller in the USB subsystem interprets the binary input information flow in the form of FPGA information and generates the programming instructions, data, and control signals for Xilinx devices. By using a simple IEEE 1149.1 (JTAG) interface, Xilinx devices are easily programmed and tested without using expensive hardware. Multiple devices can be daisy-chained, permitting a single 4-wire Test Access Port (TAP) to control any number of Xilinx devices or other JTAG-compatible devices.

3. Loading the self-test program.

4. Loading the tester operating program.

The USB Controller manages the loading of test programs.

FIG. 12 shows a block diagram of the sequencer. The sequencer is a small state machine which generates an instruction address on each 266 MHz cycle that drives the instruction memory, which in turn generates a microinstruction used to determine the operations performed by different parts of the tester.

A test consists of a sequence of instructions implementing the test algorithm. The instructions are stored in synchronous static RAM (SSRAM) running at full tester speed (266 MHz).

The Sequencer contains a register of start addresses for test programs. By default, the tester is in a condition of expecting the “RUN” command. The start point for the test program is the cell corresponding to the address contained in the start address register. The “RUN” command pushes the program from the “expecting” mode to performance of the command. The Sequencer generates addresses for the instructions according to the input instructions, and a vector of events. Every new address defines a new instruction and new data. The instructions control both the Address Generator and Data Generator. The next instruction address proceeds directly from instruction word (“jump” or “call” “subroutine” operation) or from the interrupt vector register (interrupt from timer 0) or from the LIFO (return from interrupt or “subroutine”) or from the incrementer (previous address plus one). Loop counter with a LIFO allows nested loops. The loop count as well as other registers (timers, interrupt vector register, frequency and prescaler registers) are loaded directly from the instruction word.

Besides the eighteen bits which can be used for addressing, there are ten bits in instruction static RAM used for sequencer control:

five bits for operation code,

four bits to specify branch condition,

interrupt enable bit,

three bits for control local bus,

five bits for external control.

| | | | | | | | | | | | | | | | | | | |
|---|---|---|---|---|---|---|---|---|---|---|---|---|---|---|---|---|---|---|
| 3 | . . . | 18 | 1 | . . . | 13 | 1 | 1 | 10 | 9 | 8 | 7 | 6 | 5 | 4 | 3 | 2 | 1 | 0 |
| 5 | | | 7 | | | 2 | 1 | | | | | | | | | | | |

| | | | | | |
|---|---|---|---|---|---|
| Data | ControlRe | COPLB | I | COP | COND |
| | gister | | E | | |

The list of available operations includes (COP):

non operation (non_op=0)

jump if condition is true (jump_cond_true=1)

jump if condition is false (jump_cond_false=2)

call “subroutine” (push=3)

return from interrupt or “subroutine” (pop=4)

jump if loop count is not zero and decrement the loop counter (d_loop_counter=5)

enter in new loop (load_loop=6)

load the interrupt vector and clear the interrupt counte (load_v=7)

load timer 0 low word (load_t0I=8)

load timer 0 high word and start the timer (load_t0h=9)

load timer 1 low word (load_t₁I=10)

load timer 1 high word and start the timer (load_t1h=11)

load timer 2 low word (load_t2l=12)

load timer 2 high word and start the timer (load_t2h=13)

load frequency register (load_f=14)

load Prescaler high word and start the timer (load_pI=15)

load Prescaler low word (load_ph=16)

done “subroutine” (done_op=17)

done work (finish_op=18)

The list of available operations for the controller of local bus includes (COPLB):

load length counter of the Local Bus Controller (load_length=1)

load command register of the Local Bus Controller (load_cmd=2)

load initial address of the Local Bus Controller (load_addr=3)

In order to avoid glitches in all two word registers, the value actually goes to the register during the high word write operation (an auxiliary register for low word is used).

If the sequencer gets any kind of “jumplike” operation it switches the multiplexer input to the incrementor for seven cycles, so the earliest seven operation codes after the jump will be ignored, and the “increment the current instruction address” operation will be performed.

Jumps are pipelined, but are loaded into the Instruction Memory with a shift upwards in the program flow equal to the pipeline delay (seven times). This means the jump appears to execute with zero delay. Condition jumps (branches) have the same shift applied but Interrupts are correctly handled in the case of any applicable operations. An additional pipe stage before LIFO is added to handle interrupts during “jumplike” operations. Interrupts are only disabled if there are four instructions after any kind of “jump”.

The sequencer has a register and a multiplexer to route external addresses to the APG instruction memory in multi-APG configurations.

The Prescaler is an additional timer. The Prescaler allows a condition of the Sequencer to be blocked. As a result, a delay in the generation of target signals without a change of clock frequency becomes possible. The SystemClock is a state machine, which blocks the work of the sequencer up to the moment of capture of frequencies in all FPGAs.

In operation, after configuration (and also after system reset or the end of the testing program) the flag Run is established in a low condition. In this condition, the address in the address counter (zero by default) is put on the InstructionAddress bus, and the flag FlagOfWork is translated in a low condition. The Controller of the USB Local Bus loads the memories according to the data and testing program information from the USB. After the memories are loaded, the command word from the USB recorded in the register permits a change in the condition of the Sequencer (the Run flag is established in a high condition). The read value from the memory acts through input buffers in the decoding block of a team (Decoder command—DC). The Decoder command analyses the team COP, the field COND and the vector of events, and sets command signals. The control signals determine actions according to the data received: Loading the timers, the counter for the number of repetitions, and the vector of interruption; storing in or extraction from, a stack of values of the current address and counter of repetitions. If the program has a bifurcation, then the input buffers are masked by zero for 5 clocks (input command is Nop) The timers, Timer1 and Timer2, work in unitary fashion after their initial values are loaded. The timer Timer0 works periodically, developing a signal for hardware interruption. The given signal may be masked by the enable interruption bit in the code of operation EI. The CounterIRQ calculates the number of operations performed by the timer Timer0 independently of the condition of the enable interruption bit. The IRQ signal is high, unless the counter CounterIRQ is empty. Each transition of an interrupt vector reduces the contents of the counter CounterIRQ. The value of the interrupt vector is stored in the register VectorIRQ. The timer Prescaler is started periodically unless the factor of downturn of speed of work is written as zero. Otherwise the output of the timer is established as high. If the output of the timer Prescaler is high, the address and contents of the input buffers may be updated. If the Prescaler output is low, the value on the InstructionAddress bus is locked and no changes can be made in the address counter or in the input buffers. A zero condition in the timer Prescaler does not influence the operation of the timers. Their operation is defined only by the current system frequency. The Sequencer is realised on the FPGA together with the Local Bus Controller.

The Data Generator can work in three modes: formation of a vector of the data according to a sample stored in the data memory; functional generation of the data according to the current DUT address; and generation of the data under the pseudo-random law. The APG allows the initial value to be changed by the random generator. The data polarity can be changed by loading the coding table. The Address Generator forms the address for the DUT, using an overloaded incrementing/decrementing address register. The Address Generator is able to correctly form a sequence of addresses for testing memory in burst mode. It may make a code conversion of the address according to the overloaded scramble table. The APG assumes an operative multiple reduction of the speed of formation of test signals without any change of system clock frequency or test program code. The test program code can also operate the system clock frequency.

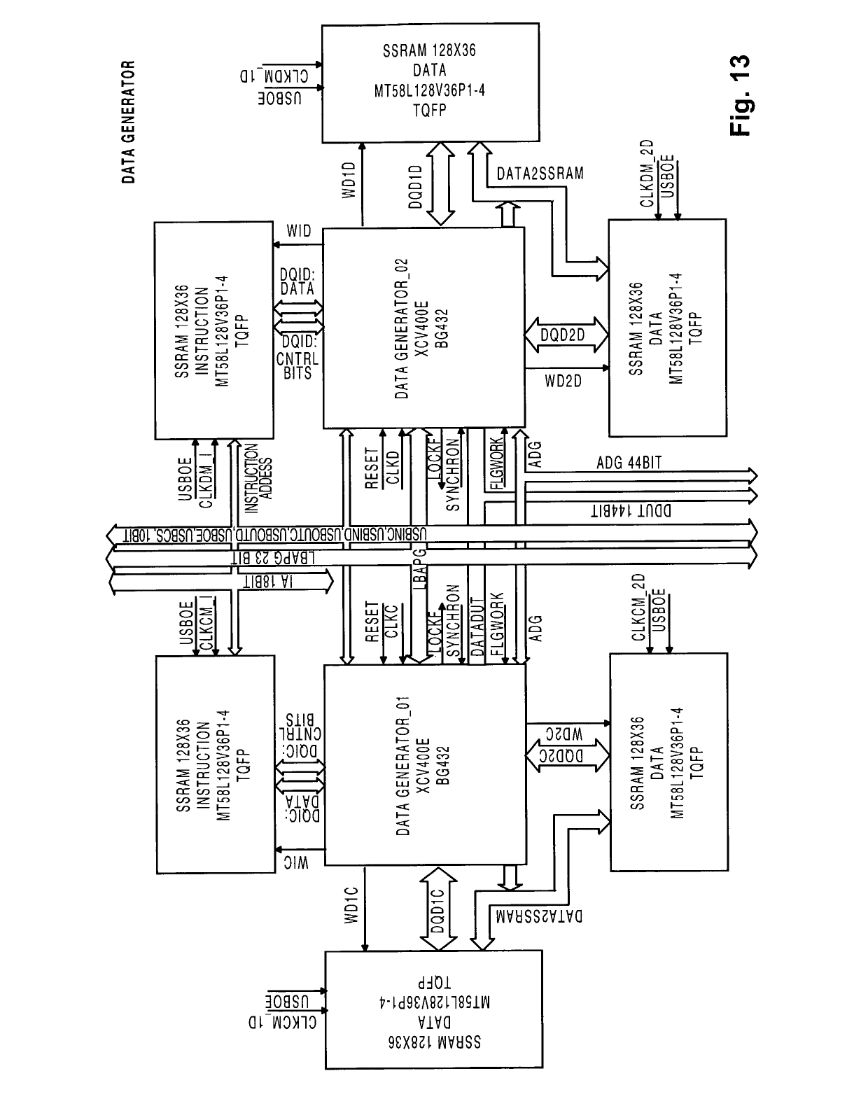

FIG. 13 shows a functional diagram of the address generator.

The Address Generator takes a field from the instruction memory and generates an address to the DUT. Generally, there are three parts in a DUT address: row, column and bank addresses. Thus, there are three main counters, each of them having a LIFO. Later row and column addresses go through adders where row and column counts are added to row and column index counts, respectively. Both index counters also have a LIFO. A special register can mask the column index counter (it is necessary to mask out bits which after mapping become less significant and are covered by the burst counter). All counters except the column index counter are actually adders, each with an additional register, and can perform the following operations: add a constant, subtract a constant, load initial count, load the constant, push the count, and pop the count.

The column index counter can perform the following operations: increment the count after a mask, decrement the count after a mask, load initial count, load the mask, push the count, and pop the count.

All consistent operations can be performed within the same cycle.

All addresses go to a scrambler for address mapping. The scrambler is controlled via the interface control block (several possible mappings are stored in the data SSRAM of the Local Bus Controller block). It is possible to switch the scrambler off on the fly.

The scramblers is a look-up table (LUT) converter. With help of the LUT, the scrambler makes function conversions in accordance with

$${A}_{i} = {{Xor}_{j = 0}}^{N} ( {\overline{α}}_{ij} \& {B}_{j} )$$

where B_{I} is i-bit of the logical address, Aⱼ—j-bit of the physical (DUT) address, αᵢⱼ—constants of the LUTs. The Data Polarity Control makes function conversions in accordance with

$${P}_{i} = {D}_{i} Xor ( {{Xor}_{j = 0}}^{N} ( {α}_{ij} \& {B}_{j} ) )$$

where P_{I}, Dᵢ are i-bits of the data DUT after and before polarity conversion.

A pseudo random shift register is capable of producing random addresses. A pseudo random generator is based upon Linear Feedback Shift Registers (LFSRs).

The heart of the pseudo random generator is the LFSR. LFSRs sequence through (2 N−1) states, where N is the number of registers in the LFSR. The contents of the registers are shifted right by one position at each clock cycle. The feedback from taps to the left-most register are XOR-ed together. The number of stages in the shift register, the number of taps in the feedback path and the position of each tap in the shift register stage in LFSRs are variable.

The register of the mask defines these variables. The random generator determines the initial starting condition of the shift register.

The number of independent m-sequences (S), for a given length of shift register is defined by:

S≦(L−1)÷N,

where N is the Shift Register Length, L is the Maximal Length Sequence. A maximal length sequence for a shift register of length N is referred to as an m-sequence, and is defined as:

L=2 N−1

In the Address Generator there are two copies of the row address at the address generator output: one goes to the protocol control block on the header and the other goes to the data generator and the fault logger. The second one is pipelined, allowing useless gaps in patterns testing protocol memory like Rambus to be eliminated (it is possible to activate new rows while you are awaiting the last read data).

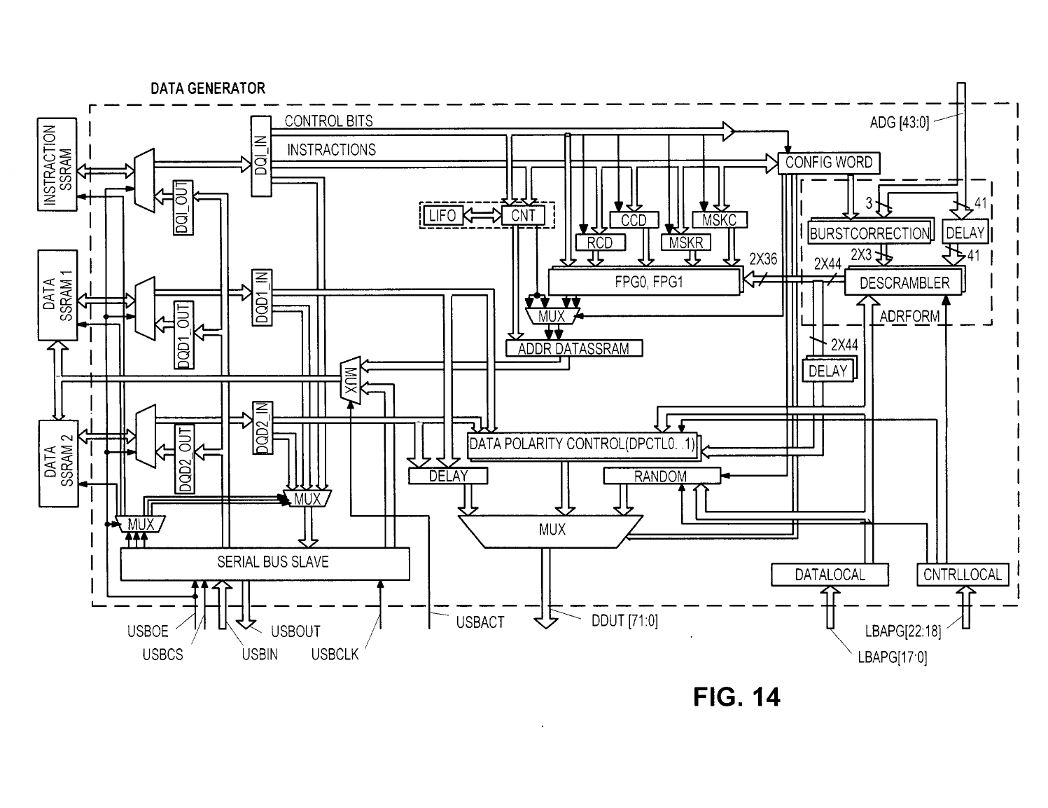

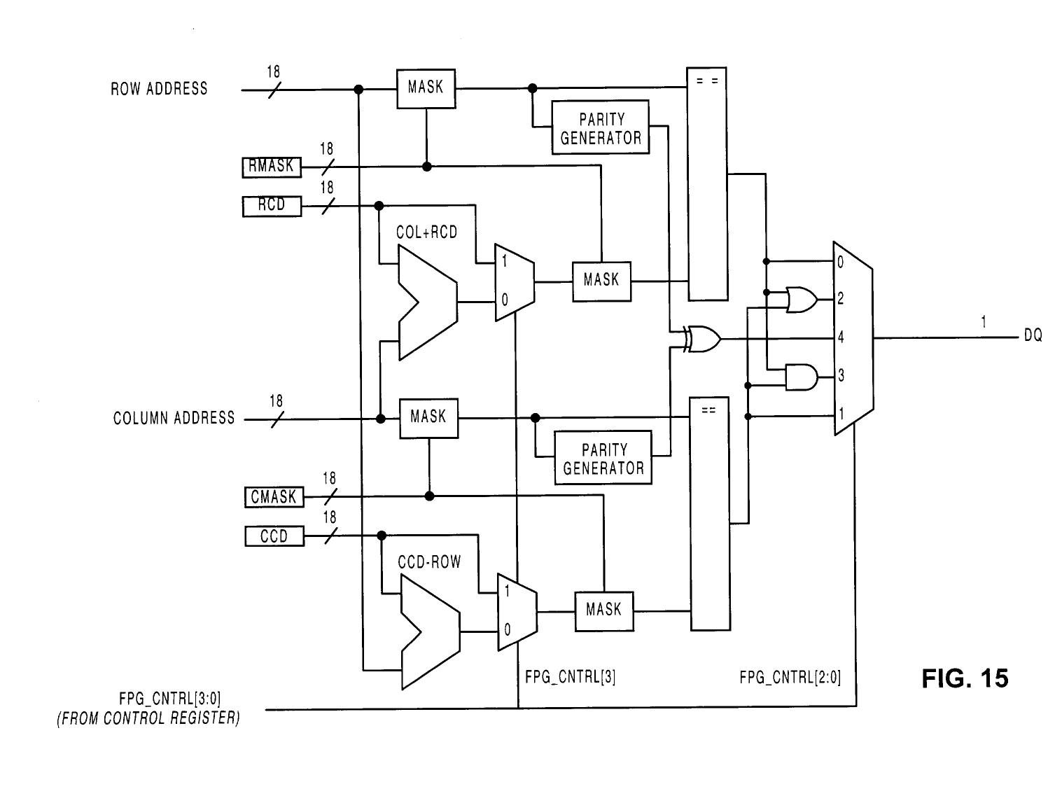

FIGS. 14 and 15 show a functional diagram of the data generator.

The data generator consists of two identical parts and is realised on two FPGAs. Each part provides 72 bits of data and works independently of the other.

The Data generator forms the data on the basis of the given patterns from the memory, or on the basis of the current address. The data patterns are stored in the data SSRAM. A counter with a LIFO provides addresses for the RAM. It increments the count by a constant written in a register.

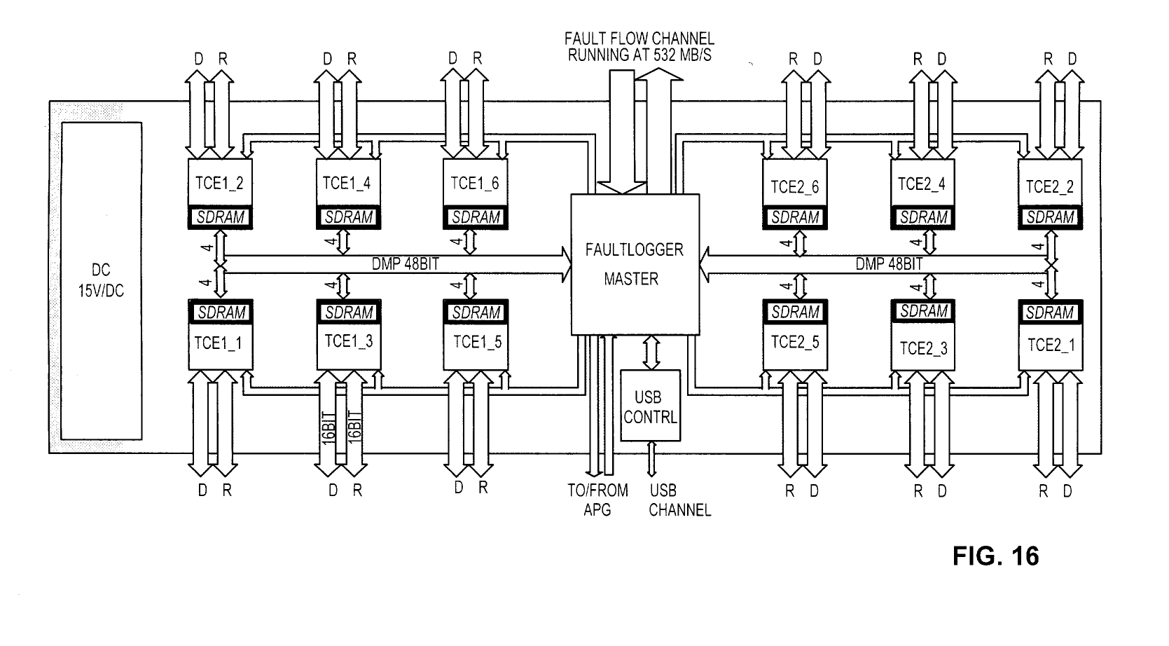

The Functional Pattern Generator (FPG) generates a data pattern as a combinatorial function of the DUT address. It supports several predefined functions (i.e. data registers). A block diagram of one of the two FPGs is shown in FIG. 16.

The ROW ADDRESS and COLUMNN ADDRESS are logical addresses coming directly from the Address Generator after descrambling transformation. The address, dynamically changing during test execution, is the main input variable for the FPG.

The FPG_CNTRL[3:0] signal is semi-static during test execution; it comes from the memory of the Instruction. This signal selects one of predefined functions implemented in the FPG.

The greyed blocks: RMASK, CMASK, RCD and CCD are registers controllable from within the test, by means of an appropriate Special Mode instruction. The contents of these registers can be considered semi-static, i.e. they change rarely during a test execution.

The RMASK and CMASK blocks represent registers storing per-bit masks for Row Address and Columnn Address respectively. Writing a “0” into a certain bit of the mask register results in the corresponding bit of the address being excluded of the FPG function. The MASK blocks apply the masks to the address. Using different masks allows a great variety of data patterns to be created.

Each of the two arithmetic units implements a single arithmetic operation indicated in FIG. 16. The PARITY GENERATOR block generates a one on its output when the number of ones on its input is odd, otherwise it generates a zero. The digital comparator block (labelled “==”) generates a one on its output when values on its inputs are equal to each other.

The output FPGs are treated as younger bits in the address, on which the values of data for the DUT are stored. This allows opportunities for operative change in the FPG of the kind of patterns appropriate “0” and “1” to be expanded.

In the Data Generator there are four sets of descramblers (two descramblers per the unit) and functional pattern generators, which provide true data polarity and data can be generated from addresses even in interleaving burst mode. Also, there are four sets of Data Polarity Controls (two descramblers per the unit). Each bit of the Data PolarityControls controls the polarity of the corresponding bit of the test data. When a control bit is HIGH the data bit is inverted.

The descramblers and the Data Polarity Controls are look-up table (LUT) converters. With help of the LUTs, the descrambler makes function conversions in accordance with:

$${B}_{i} = {{Xor}_{j = 0}}^{N} ( {α}_{ij} \& {A}_{j} )$$

where B_{I} is i-bit of the logical address, Aⱼ—j-bit of the physical (DUT) address, αᵢⱼ-constants of the LUTs. The Data Polarity Control makes function conversions in accordance with:

$${P}_{i} = {D}_{i} Xor ( {{Xor}_{j = 0}}^{N} ( {α}_{ij} \& {B}_{j} ) )$$

where P_{I}, Dᵢ are I-bit of the DUT data after and before polarity controls.

In the Data Generator there is the Burst Correction block, which transforms the DUT address under burst mode. The address is formed on each step independently of the mode of work. However in burst mode part of addresses is latent because of the subsequent temporary multiplexing of the data. The address is corrected according to the current physical address and the contents of the command word register. The command word register defines the burst length and the order of addressing within a burst. A pseudo random shift register is capable of producing random data. The initial value of the data of the Local Bus Controller is stored in the memory, so the data sequence can be repeated if needed.

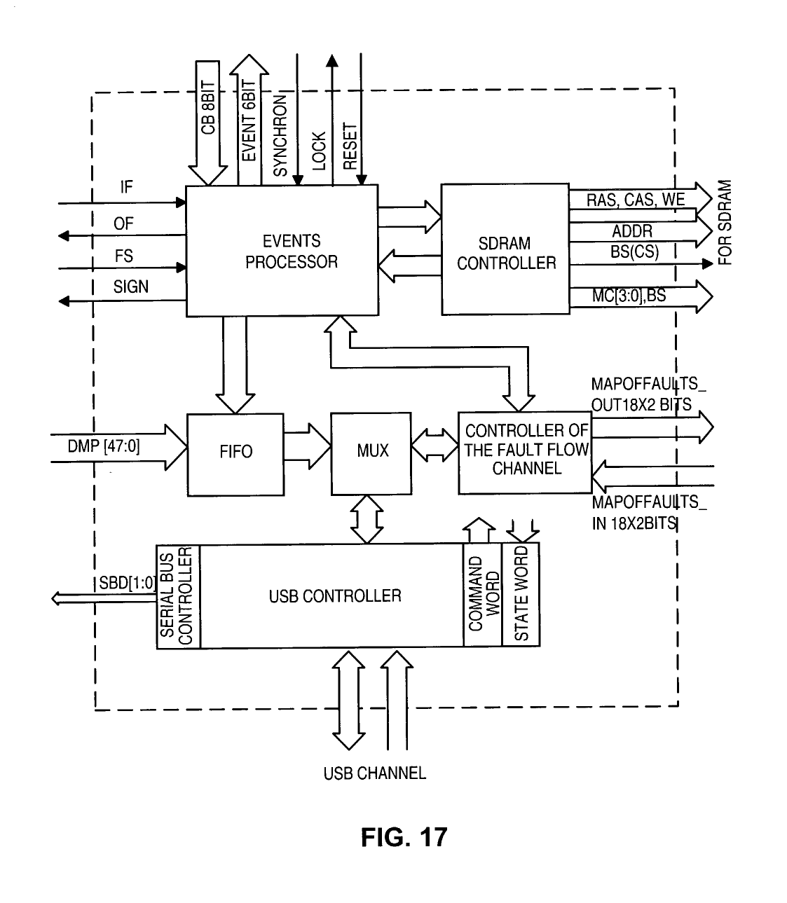

FIG. 17 shows a functional diagram of the fault logger.

The Fault Logger consists of two basic parts: a Fault Logger Master and a Systolic Elements.

The Fault Logger Master provides interface between the Systolic Elements and other parts of the system, synchronizes the process of recording and reading faults in/from the memory, forms a fault output flow, controls the overflow and emptying of memories, records teams in the Systolic Element. The Fault Logger Master provides interaction with the USB controller.

The Systolic Element modules perform elementary transformations of the above DQ input data, perform comparisons, and store them in the buffer memory. The Systolic Elements are built in series. The serial number of the Systolic Element defines the address of Systolic Element in the system. The Fault Logger Master periodically develops a pulse “signature” (SIGN net). The Systolic Elements define the address and delays which are necessary for work with help of these pulses. The DQ input signals correspond to levels and requirements SSTL 2-1. If there is an error on any DQ, the corresponding Systolic Element sets a flag identifying the error in the IFE or IFO, which are consistently transferred from one Systolic Element to the next. Signals identifying the erroroneous data from the i-Systolic Element are combined with signals of the error data detained on (N−i+1)*k of steps in the (i—1) Systolic Element, where N− is the number of the Systolic Element in a series, k is number of the steps necessary for transmission through one Systolic Element. As a result, the signals thus generated inform the Fault Logger Master of the presence of the erroneous data in the DQ along the full length of the line on (N+1)*k one step earlier. The Fault Logger Master generates signals OFE or OFO to record the DQ vector in the buffer memory in the Systolic Element.

The occurrence of the mistaken data initialises reading of data from the buffer memory in the Systolic Element to the channel Dmp in 96 bit width, with speed 96 MHz. The Fault Logger Master drives reading and writing of the data in the memory using the MS (4 bits) bus. The Fault Logger Master transfers the read data to the USB controller or to the high-speed bus MapOfFaults_Out. The MapOfFaults_Out bus is connected with the Flow Fault Channel.

The Flow Fault Channel is adapted to the signaling levels and requirements of LVDS signaling. The topology of the Fault Logger allows the reverse procedure to be performed: loading the memory according to the data and distributing it on the external bus. Thus, the Fault Logger can operate as a generator of test influences. This function will be made possible in the next revision of the Fault Logger.

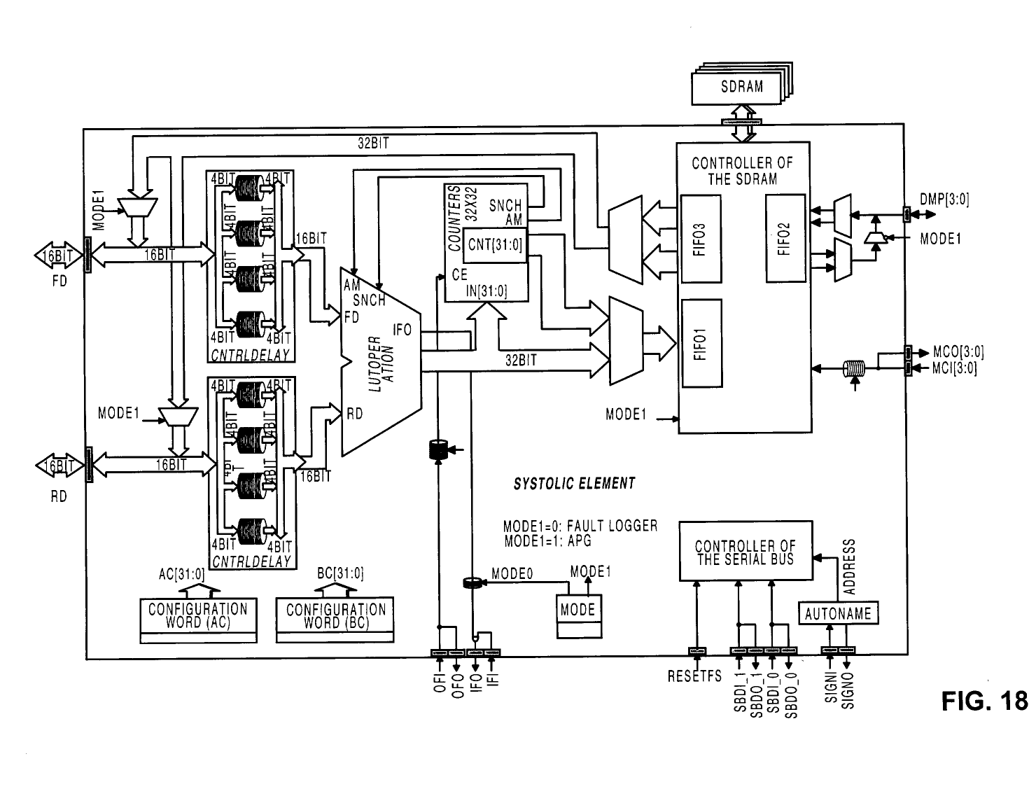

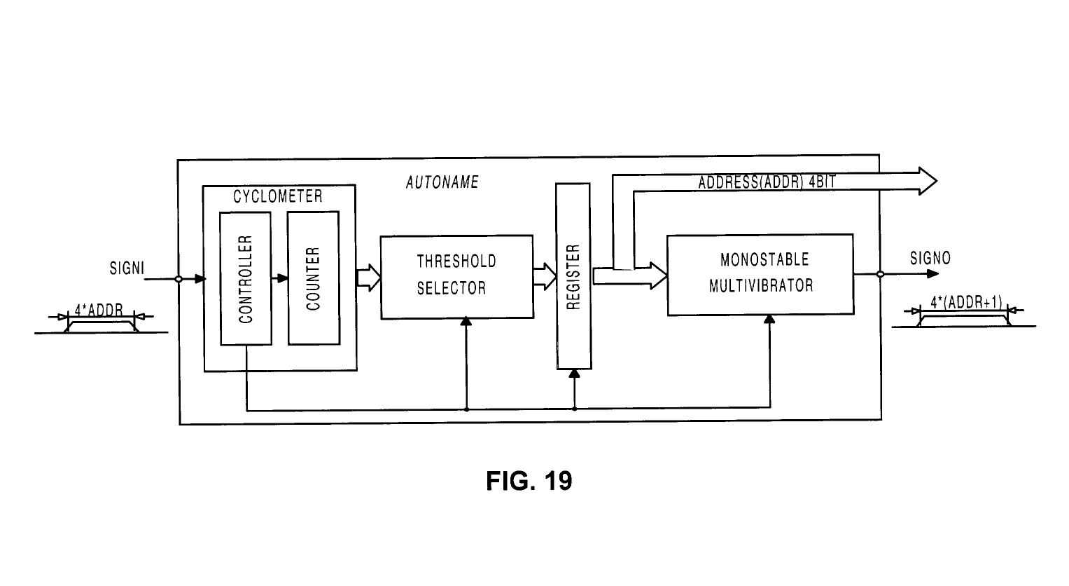

Functional diagrams of the Fault Logger Master and Systolic Element are shown in FIGS. 18 and 19.

The Fault Logger can operate in several modes. Each mode can operate with data arriving at a rate of 266 Mbps per DQ, or transmission at 266 Mbps per DQ.

In data capture mode, the fault logger can store 384 bits of data per cycle. In vector logging mode, the fault logger can store 384 bits of data per cycle. In bitmap capture mode, the fault logger can store 144 bits, where 144 bits are used for reference. In vector fault logging mode, the fault logger can store 144 bits where 144 bits are used for reference data. In vector generation mode, the fault logger can generate 384 bits of data. In counter mode, the number of fault events per DQ is logged, with a 32 bit count limit. The counter is protected from overflow. The address of the first failure is also logged per DQ. No fault memory need be fitted to the fault logger if this is the only mode the fault logger must operate in. In counter mode the fault logger compares the incoming data with that generated by the APG.

In all modes, each DQ can be masked based on the contents of a 32 bit counter per DQ reaching a preset limit. After the bit is masked the counter continues to count, but all fault logging from that DQ is masked.

The fault logger memory is a FIFO constructed from a SDRAM and FPGA.

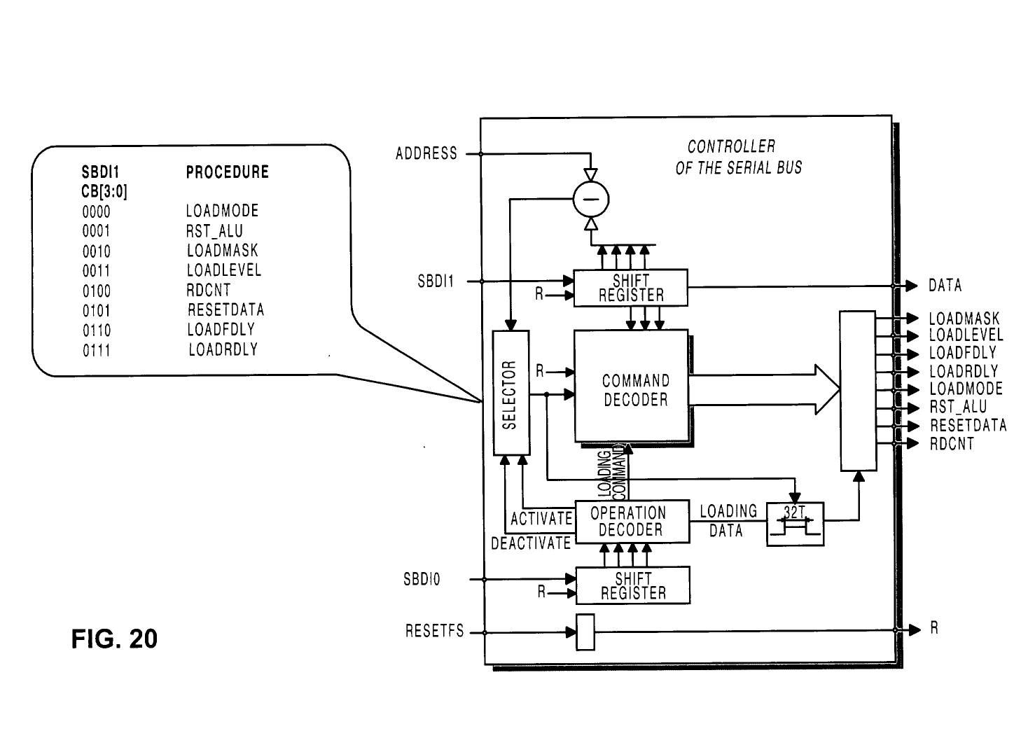

The Fault Logger is built on 24 circuit element Systolic Elements (SE_j, j=1 . . . 24). Every SE is able to define its own address in system and delays, necessary for work. For this purpose SE_j uses an input SIGN_ij (signal from SE_i) and output SIGN_jk (signal to SE_k). All SE_j are consistently incorporated by connections SIGN_ij—SIGN_jk. If the pulse on an input SIGN_ij has a duration of not less than 4 steps, that is its address. Once the SE_j has received a pulse, it sends it to the next SE_k. The send pulse is longer that the received pulse by one step. An embodiment of a circuit for realizing the address decoder is shown in FIG. 20.

The Systolic Element has a control register in the Indexer.

The field Mode in the control register defines the Fault Logger's modes of operation:

Command definition is the work Systolic Element. The commands defined by the Systolic Element move from the USB or APG through the Fault Logger Master on the SBData and Dmp buses. The format of commands is shown in the following table 1:

TABLE 1
The format of commands
Commands for typical computing element(TCE) of FaultLogger

| | |
|---|---|
| SB_Data[0]—data enable | |
| SB_Data[1]—comand enable | |
| SB_Data[2]—comand data | |
| Format:COP=3bit | |
| | Code operation(COP) |
| Write control word in the TCE | 3′b001 |
| Write Mask | 3′b010 |
| Write level of autolimited of the fault counters | 3′b011 |
| Unload all counters | 3′b100 |
| Reserved | 3′b101 |
| Reset DLLs | 3′b110 |
| Reset TCE | 3′b111 |

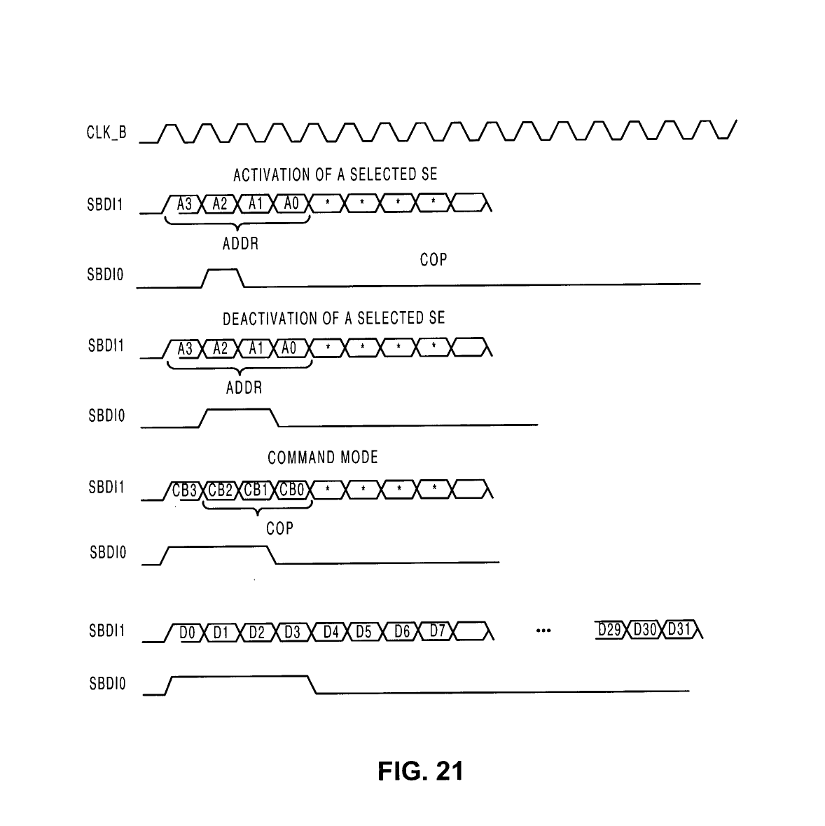

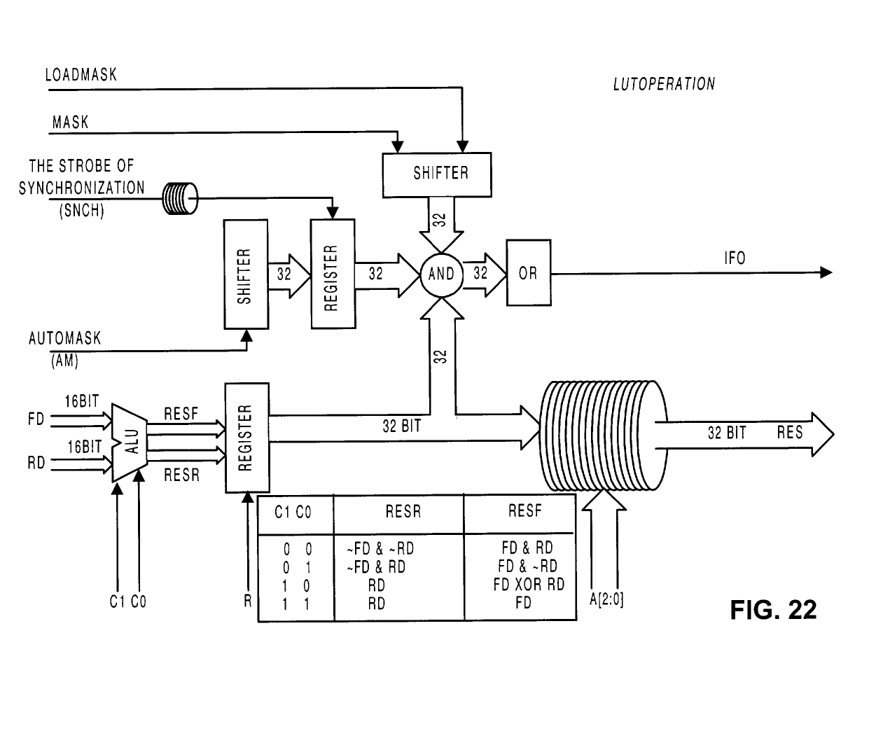

A Serial Bus Controller receives the data and decodes it within the module Indexer InDC. A scheme of the Serial Bus Controller and a timing diagram illustrating its operation are shown in FIGS. 21 and 22, respectively.

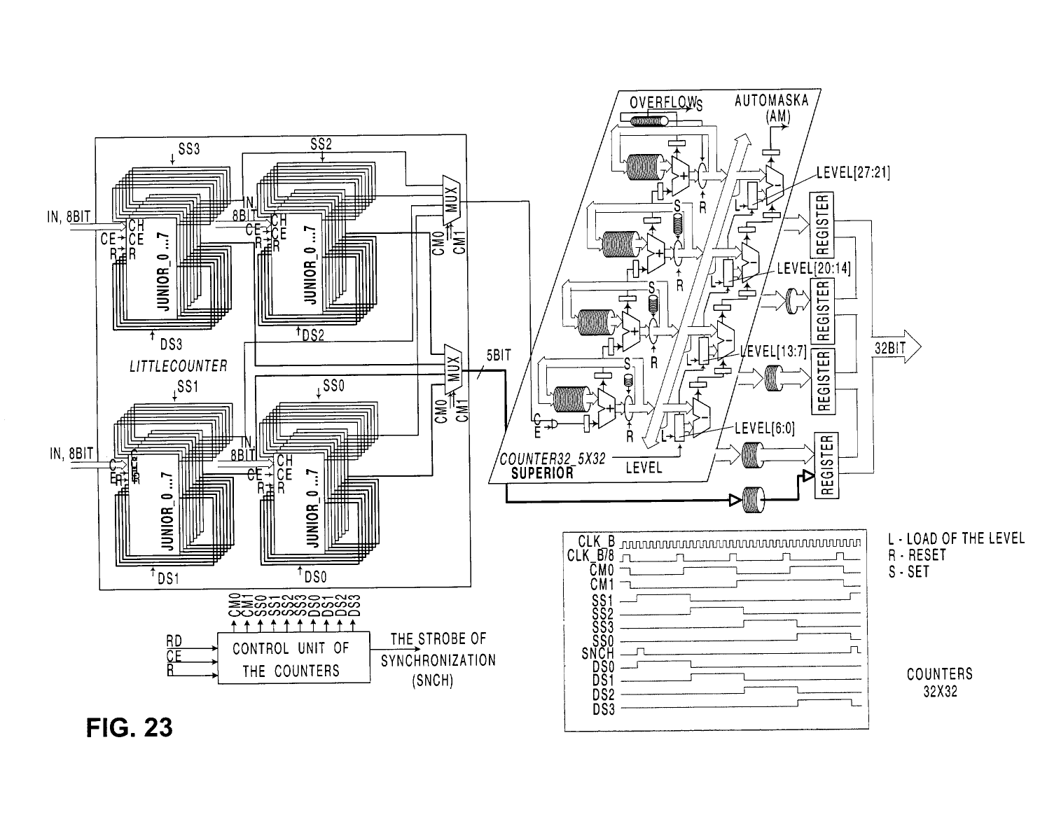

Every Systolic Element processes 8 data fault bits and 8 referent (real) bits. In order to reduce the speed requirements of the FPGA, the input data is multiplexed on an even and an odd, thus decreasing the frequency twofold. The transfer of the fault data and the real data for processing in the LUTOperators (the module of logic operations) can be delayed at the input (entrance) to every Systolic Element. The length of the delay can be up to 32 steps (CDL1 and CDL2). A function chart for the LUTOperator is shown in FIG. 23.

The LUTOperator allows various operations to be performed on the above data according to a code of teams:

| Command | Description |
|---|---|
| XXX00 | Disable transfer input data |
| XXX01 | Fault<=Fault&˜Real Real<=˜Fault&Real |
| XXX10 | Fault<=FaultReal Real<=Real |
| XXX11 | Fault<=Fault Real<=Real |
| XX1XX | Real (reference) data inversion |
| X1XXX | Fault (reference) data inversion |
| 1XXXX | Each unit in the input data is an attribute of a mistake. |

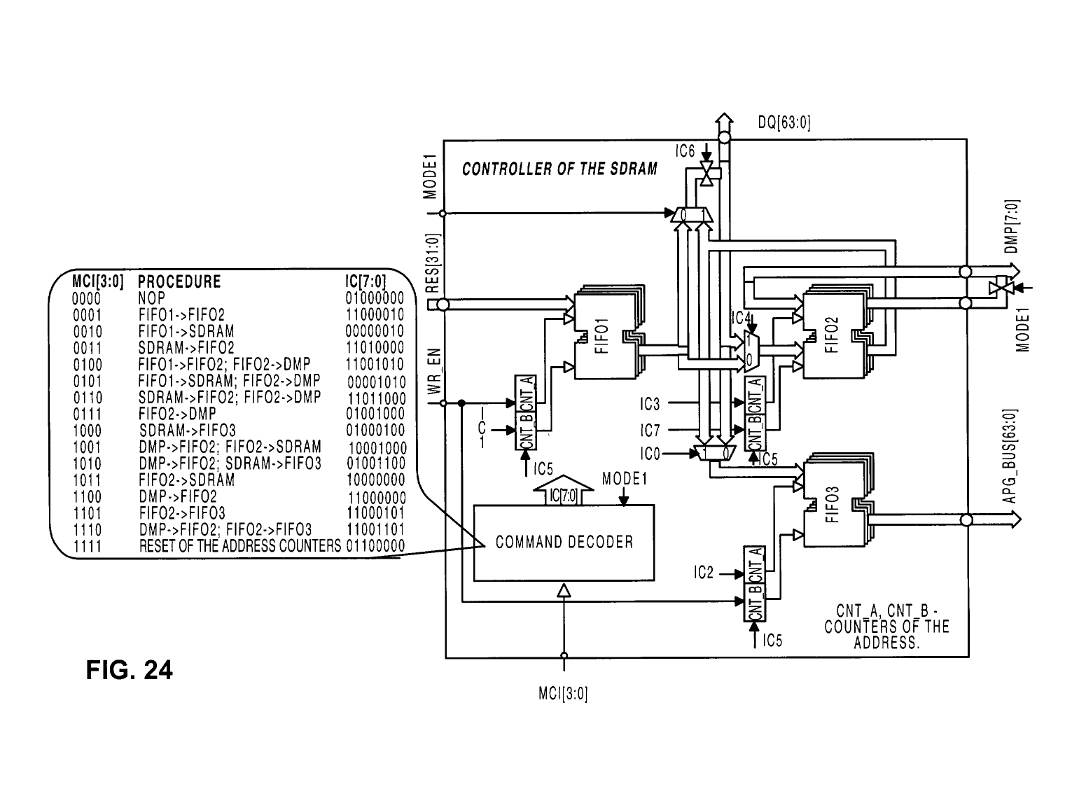

There is a DQ mask in the LUTOperation. The mask operates according to a condition of the counter and value of the mask register. The results of logic transformation in two LUTOperations are controlled by the 16 channel counters. Every “1” in the LUTOperations outputs is treated as an error and is automatically stored in the memory. If there is an error in the data, the flag Fault (IFO or IFE) is established at a high level. The fault delays for the number of steps necessary for transfer of a flag signalling the occurrence of the error from last Systolic Element in the line up to current Systolic Element. The delayed result unites with the result from the previous Systolic Element and is transferred to the subsequent one. The high level on lines InFaultO or InFaultE means that the odd or even vectors of the DQ must be recorded in the buffer memory. The structure of the multichannel faults counter is shown in FIG. 24.

The counter consists of two parts. In the first part there are sixteen normal 4 digit counters—Little Counters. The second part is the adder, Counter32_{—}5×16, at which the arguments move on the closed ring. A total rotation of the data in the ring takes 16 steps. One of arguments of the adder is the ‘carry’ signal from one of 16 younger counters. Other argument is the saved sum of previous steps on a given DQ. This organization is suitable for a multichannel counter with temporary multiplexing of channels.

The values of counters can be read in the USB through the Dmp bus or held in the SDRAM.

If the 31 bit of the counter is set high, the counter is not changing its state. The Controller SDRAM manages the accommodation of a remembered DQ vector in the memory. A function chart of the controller is given in FIG. 24.

The Fault Logger has one common module for all the Systolic Elements, which synchronizes their work and organises the flow of information. After configuration, the Fault Logger Master periodically generates a pulse on the “SIGN” net not less than 4 steps in duration, to define addresses in the Systolic Elements.

The USB and the AGP control the Fault Logger Master. The CB bus from the AGP is used by the Master Fault Logger for initialization, commencing analysis of the DQ and transferring the data.

The IFE and IFO signals inform the Fault Logger Master of the occurrence of faults in the input vector. The Keeper module calculates the number of faults and defines the direction of movement of the data vector with the faults. The direction of movement of the data vector is defined by the value of the stored vectors in the FIFO Systolic Elements and SDRAM. The DMP bus is also used for unloading the fault counters, loading the memory and internal registers of the Systolic Element with the data. Possible sources of information are:

1. Storing of the data in the FIFO2 from FIFO1 Systolic Elements;

2. Storing of the data in the SDRAM from the FIFO1;

3. Reading from the SDRAM in the FIFO2 Systolic Elements;

4. Reading from the FIFO2 Systolic Elements in the DMP bus.

5. Storing in the FIFO2 Systolic Elements from the DMP;

6. Storing in the SDRAM from the FIFO2;

7. Reading from the SDRAM in the FIFO1 Systolic Elements;

8. Reading from the FIFO2 in the FIFO1 Systolic Elements.

To define the chosen method, the Keeper forms commands for the DrvMem module (see the following table 2).

TABLE 2
Commands for memory control

| Command | Description |
|---|---|
| Flag_up | SDRAM is on: precharge all bank, autorefresh, |
| | load mode(LAT3, BL256, Sequence) |
| Flag_down (optional) | SDRAM is off (sleep mode) |
| Flag_write_1 | Write 128 words from the fifo1 to the SDRAM |
| Flag_read_2 | Read 128 words from the SDRAM to the fifo2 |
| Flag_fifo_12 | Write from the fifo1 to the fifo2 |
| Flag_refresh | Refresh of the SDRAM |
| Flag_write_2 | Write 128 words from the fifo2 to the SDRAM |
| Flag_read_1 | Read 128 words from the SDRAM to the fifo1 |
| Flag_fifo_21 | Write from the fifo2 to the fifo1 |

The command from the Keeper module forces on the DrvMem module to generate the necessary sequence of instructions for management of the memory and the FIFO. A list of instructions for the DrvMem module is given in the following table 3.

TABLE 3
List of instructions for the DrvMem module

| Instraction | Code | Discription |
|---|---|---|
| Nopz | 0 | Not operation, bus DQ of the memory has |
| | | Z-state |
| Auto_refresh | 1 | Auto refresh |
| Precharge_all_bank | 2 | Precharge all bank |
| Write_CA | 3 | Command write & Column Address |
| Write_CA_AP | 4 | Command write & Column Address & |
| | | Auto Precharge |
| Read_CA | 5 | Command read & Column Address |
| Read_CA_AP | 6 | Command read & Column Address & |
| | | Auto Precharge |
| Power_down | 7 | Power down |
| Load_mode | 8 | Load mode 1 (LAT=3,BL=256,Seq) |
| Active_bank | 9 | Activate current bank |
| Nop | 10 | Not operation |
| Fifo12 | 11 | Write from fifo1 to fifo2 |
| Fifo21 | 12 | Write from fifo2 to fifo1 |
| Burst_term | 13 | Burst terminate |
| WriteFifo | 14 | Write from BMP to fifo2 |
| ReadFifo | 15 | Write from fifo2 to BMP |

The reading of vectors of a card faults occurs on the DMP bus. The reading of four 16 bits words from Systolic Element is made during 16 steps by 4 bits. In result, on the DMP bus creates of a data vector with common word length by 96 bits and maximal frequency of following 96 MHz. The data from DMP are remembered in FIFO of the Fault Logger Master. These data further can be transferred either in the USB channel or in the Flow Fault Channel through the MapOfFaults_Out bus. The Flow Fault Channel is high-speed bus and provides the maximal possible speed of transfer of the data for AGP-4x.

The basic technique used in Flow Fault Channel is known as source synchronous signaling, which drives clock and data from a single device and forwards the clock along with the data to the destination. Clock and data propagate along adjacent paths with matched time delays.

FIG. 25 shows a complete LVDS link, with 17 data channels running at 576 Mb/s and one clock channel running at 288 MHz. The transmitters on the left use both edges of the clock to transmit data driven by a clock multiplexer onto the LVDS channel. Clock and data delays are well matched since identical multiplexers generate both clock and data. Clock and data pass through the Virtex-E LVDS driver circuitry and off chip. The source termination network adjusts the levels to be fully LVDS compliant and also provides source termination of the transmission lines to 50 Ohms, attenuating any reflected signals going back to the driver. The transmission lines can be microstrip or stripline at 50 Ohms to ground, or twisted pair with 100 Ohms differential impedance. The parallel terminator generally consists of a bank of 100 Ohms resistors across each differential pair. For maximum timing margin at 576 Mb/s, the clock should be delayed by 1.1 ns relative to the data, using either additional trace delay or a driver with well-characterised propagation delay.

The signals are received by the differential LVDS receivers and pass to flip-flops that sample the data on the rising and falling edge of the forwarded 288 MHz clock. Data can be further demultiplexed down to 96 MHz using a block RAM structure.

FIG. 26 shows an LVDS receiver connected to an LVDS transmitter on a single Virtex-E FPGA (where the Master Fault Logger is placed). The receiver accepts 17 data channels at 576 Mb/s each and one clock channel at 288 MHz. The clock channel is located between the half data channels to equalize the sampling time on the two half data channels. Placing the clock in the middle provides equal distance to both half sampling channels in the FPGA.

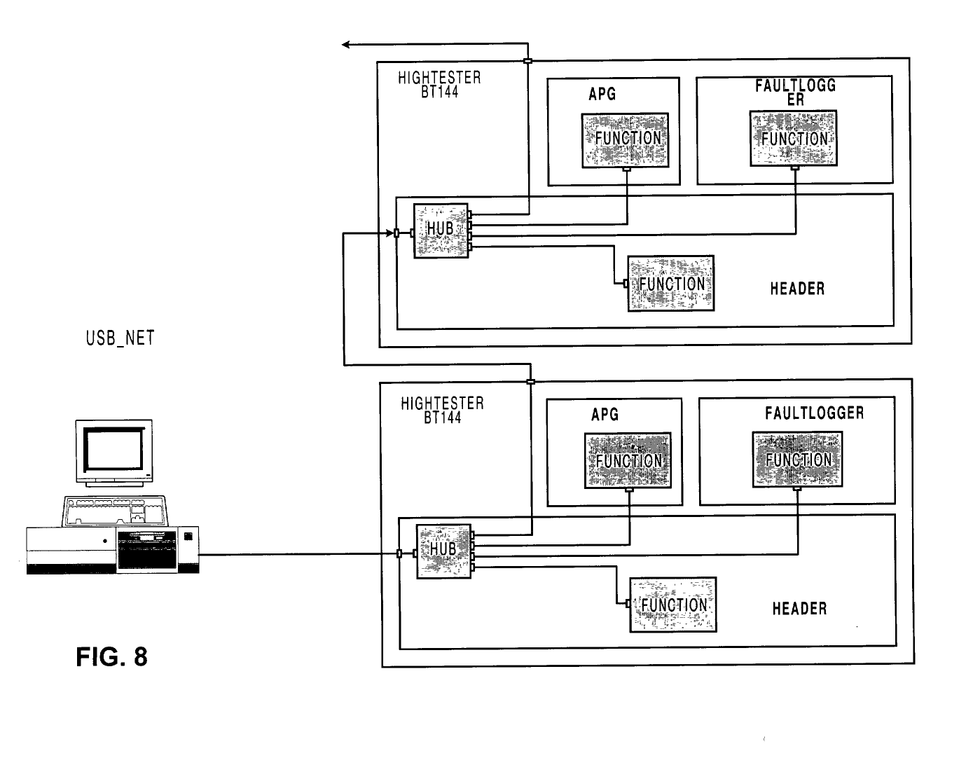

The structure of a system using a USB network is shown in FIG. 8. The USB provides an exchange of data between the host-computer and number of peripheral devices.

The host computer may be the built-in PC or an external computer. The host distributes a throughput from the trunk to the connected devices, with the help of markers. The net allows devices to be connected, configured, used and disconnected in work time. The purposes of the USB are:

1. Initialization of the High Tester;

2. Loading the test program;

3. Loading constants;

4. Adjustment of the tester;

5. Starting the test process;

6. Stopping the test process if the alarm is activated;

7. Changing the test program (branching the program);

8. Monitoring tester status;

9. Unloading the results of testing.

10. Diagnostics of the High Tester.

The USB uses the CY7C64613-128 (EZ_USB FX) to implement the USB protocol, with additonal support from an FPGA. The FX builds on the EZ-USB feature set, including an intelligent USB core, enhanced 8051, 8-Kbyte RAM, and high-performance I/O. The CY7C64613 enhances the EZ-USB family by providing faster operation and more ways to transfer data into and out of the chip at very high speed.

Program code can be downloaded into on-chip RAM on the CY7C64613 via the USB cable, eliminating the need for external program memory or mask ROM headaches. The properties of the controller USB, except for support of the protocol of an exchange on the channel, allow easy realisation of functions via JTAG for loading the FPGA. Using this route, it is possible to eliminate completely all EEPROM from the system.

The invention has been explained with reference to specific embodiments. Other embodiments are contemplated without departing from the spirit and scope of the invention. It is therefore not intended that this invention be limited except as indicated by the appended claims.

What is claimed:

1. A test apparatus for testing a memory device, the test apparatus comprising:
a scalable algorithmic test pattern generator for generating test instructions,
a detachable header for connecting to a memory device under test (DUT); and
a fault logger for analyzing results of the test, connected to the DUT;
the test pattern generator, the header, DUT and fault logger being connected in series, wherein the test pattern generator includes a sequencer, an address generator and a data generator, the sequencer being operated independently from the operation of the data and address generators, thereby providing for the high speed conveyor transmission and treatment of data within the test apparatus.

2. The tester of claim 1, wherein each said test instruction has separate fields controlling the sequencer, the address generator and the data generator, respectively.

3. The tester of claim 1, wherein the sequencer, the address generator and the data generator are each in communication with an instruction memory.

4. The tester of claim 1, wherein the detachable header comprises a header board connected to the pattern generator and the fault logger, and a memory device interface board connected to the header board via pin electronics cards.

5. The tester of claim 1, wherein the test pattern generator comprises more than one data generator.

6. The tester of claim 1, wherein the address generator is segmented into three units, including row generator, column generator and bank generator, thereby a test vector can be generated in one machine cycle.

7. The tester of claim 1, wherein the address generator and/or data generator is implemented as a random generator.

8. The tester of claim 3, wherein control signals are stored together with data signals in the form of instruction words in the instruction memory.

9. The tester of claim 1, wherein the pattern generator is operable in three modes.

10. The tester of claim 1, wherein the pattern generator is operable to retrieve pre-calculated test vectors from the data memory, wherein the test vector can be represented by any possible sequence of “1”s and “0”s.

11. The tester of claim 1, wherein the pattern generator is operable to generate test vectors for the current DUT address using FPGA.

12. The tester of claim 1, wherein the pattern generator is operable to generate the test data as a random generator.

13. The tester of claim 8, wherein the width of the instruction word is extended by increasing the number of memory chips addressable by a test instruction sequencer.

14. The tester of claim 8, wherein each instruction word comprises at least partially or completely decoded instruction thereby the speed of generation of test vectors is increased.

15. The tester of claim 1, wherein the fault logger is segmented into a plurality of fault logger units.

16. The tester of claim 1, wherein the fault logger comprises a plurality of systolic elements enabling the segmenting of the fault logger into a plurality of fault logger units.

17. The tester of claim 1, wherein the fault logger is operated in two modes, namely, a direct mode, when the fault logger is used for the treatment of fault data, and the reverse mode, when the fault logger is used for generation of test vectors.

18. The tester of claim 1, wherein the fault logger comprises a buffer memory segmented into a plurality of memory units, wherein each unit interacts with a respective source of information.

19. The tester of claim 18, wherein the whole plurality of memory units is controlled by a common control unit.

20. The tester of claim 1, wherein several test units are operated in parallel in a master-slave manner.

21. The tester of claim 1, wherein an address generated by APG sequencer operating as a master unit is transferred to other sequencers operated as slave units, the address being the address by which instruction is retrieved from the instruction memory.

22. The tester of claim 1, wherein the test apparatus is connected to a computer provided with a computer readable program means.

23. The tester of claim 1, wherein the test apparatus is incorporated into a computer environment using any one or a combination of transmission channels selected from USB, Ethernet and LVDS channel.

24. The tester of claim 21, wherein LVDS channel is used with AGP interface card.

25. A method of testing a memory device, comprising the steps of:
generating test instructions, including the generation of test patterns, address and data, the test patterns being generated independently from generation of data and address signals;
transmitting generated test instructions to a memory device under test; and
treatment of the results of the test,
wherein the generated test instructions are transmitted to a memory device under test and the results of the test are transmitted to the step of treatment of the test results continuously in a conveyor-like manner.

26. The method of claim 24, wherein each said test instruction has different fields controlling sequence of tests, address generation and data generation.

27. The method of claim 24, wherein the address generation includes generation of rows, columns and banks, so that a test vector can be generated in one machine cycle.

28. The method of claim 24, wherein the address is generated by a random generator.

29. The method of claim 24, wherein the data is generated by a random generator.

30. The method of claim 24, wherein at least one step is computerised.

31. A computer program product for causing a test apparatus connected to a computer to test a memory device under test, the computer program product comprising a computer usable medium having computer readable program code means embodied thereon, said computer program code means comprising:
a computer readable program code means for causing a computer to operate the test apparatus for generating test instructions, including test patterns, address and data based on information stored in an instruction memory, the test patterns being generated independently from generation of data and address signals;
a computer program code means for causing a computer to operate the test apparatus for transmitting the generated test instruction to a memory device under test; and
a computer program code means for causing a computer to operate the test apparatus for subsequently analysing the results of the test;
wherein the generated test instructions are transmitted to a memory device under test and the results of the test are transmitted to the step of treatment of the test results continuously, so as to enable generation, transmission and subsequent treatment of test data and the results of the test in a conveyor-like manner.
